(19) United States
(12) Patent Application Publication
(10) Pub. No.: US 2025/0273488 A1
(43) Pub. Date: Aug. 28, 2025

(54) Heating Method, Method of Manufacturing Semiconductor Device, Substrate Processing Apparatus, Lamp Module, Method of Processing Substrate and Non-transitory Computer-readable Recording Medium

(71) Applicant: Kokusai Electric Corporation, Tokyo (JP)

(72) Inventors: Yukinori ABURATANI, Toyama (JP); Takeshi YASUI, Toyama (JP)

(21) Appl. No.: 19/065,375

(22) Filed: Feb. 27, 2025

(30) Foreign Application Priority Data
Feb. 27, 2024 (JP) 2024-027774

(51) Int. Cl. H01L 21/67

(52) U.S. Cl. CPC H01L 21/67115

(57) ABSTRACT

There is provided a technique that includes: (a) loading a substrate into a process chamber; (b) operating a heater including a lamp radiating a light and a storage storing a wiring; attenuating a heat from the lamp by a thermal attenuator at a first structure facing the lamp, wherein the first structure is provided at a holder and covers an outer periphery of the storage; and forming a heat conduction path of heat of the storage to a housing via the first structure, a second structure provided at the holder and a support of the housing, wherein the second structure protrudes outward from the first structure opposite to the lamp, and the housing is provided above the process chamber and includes an insertion structure where the first structure is inserted without contact, and the support for the second structure; and (c) heating the substrate by the heater.

### CROSS REFERENCE TO RELATED APPLICATIONS

This non-provisional U.S. patent application is based on and claims priority under 35 U.S.C. § 119 (a)-(d) of Japanese Patent Application No. 2024-027774 filed on Feb. 27, 2024, in the Japanese Patent Office, the entire contents of which are hereby incorporated by reference.

### TECHNICAL FIELD

A technique of the present disclosure relates to a heating method, a method of manufacturing a semiconductor device, a substrate processing apparatus, a lamp module, a method of processing a substrate and a non-transitory computer-readable recording medium.

### BACKGROUND

According to some related arts, a substrate in a process chamber may be heated by a light emitted (or radiated) from a lamp heater.

### SUMMARY

According to the present disclosure, there is provided a technique capable of easily inserting and removing a holder of a lamp into and from an insertion structure of a housing, while suppressing an increase in a temperature of the holder when the lamp is emitting a light.

According to an embodiment of the present disclosure, there is provided a technique that includes: (a) loading a substrate into a process chamber; (b) operating a heater including a lamp capable of radiating a light to heat the substrate and a storage capable of storing a wiring connected to the lamp; attenuating a heat generated by the light radiated from the lamp by a thermal attenuator provided at a location of a first structure facing the lamp, wherein the first structure is provided at a holder and configured to cover an outer periphery of the storage; and forming a heat conduction path of a heat of the storage to a housing via the first structure, a second structure provided at the holder and a support of the housing, wherein the second structure protrudes outward from another location of the first structure opposite to the lamp, and wherein the housing is provided above the process chamber and includes an insertion structure into which the first structure is inserted in a non-contact state and the support configured to support the second structure; and (c) heating the substrate by the heater.

### BRIEF DESCRIPTION OF THE DRAWINGS

FIG. 1 is a diagram schematically illustrating a vertical cross-section of a substrate processing apparatus preferably used in one or more embodiments of the present disclosure.

FIG. 2 is a diagram schematically illustrating an enlarged cross-section of a lamp and peripheries thereof shown in FIG. 1

FIG. 3 is a diagram schematically illustrating an arrangement of a plurality of lamps when viewed from above, wherein a configuration of each of the plurality of lamps is substantially the same as that of the lamp shown in FIG. 2.

FIG. 4 is a block diagram schematically illustrating a configuration of a controller (control structure) and related components of the substrate processing apparatus according to the embodiments of the present disclosure.

FIG. 5 is a flow chart schematically illustrating a substrate processing according to the embodiments of the present disclosure.

### DETAILED DESCRIPTION

Hereinafter, one or more embodiments (hereinafter, also simply referred to as “embodiments”) according to the present disclosure will be described with reference to the drawings. Further, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

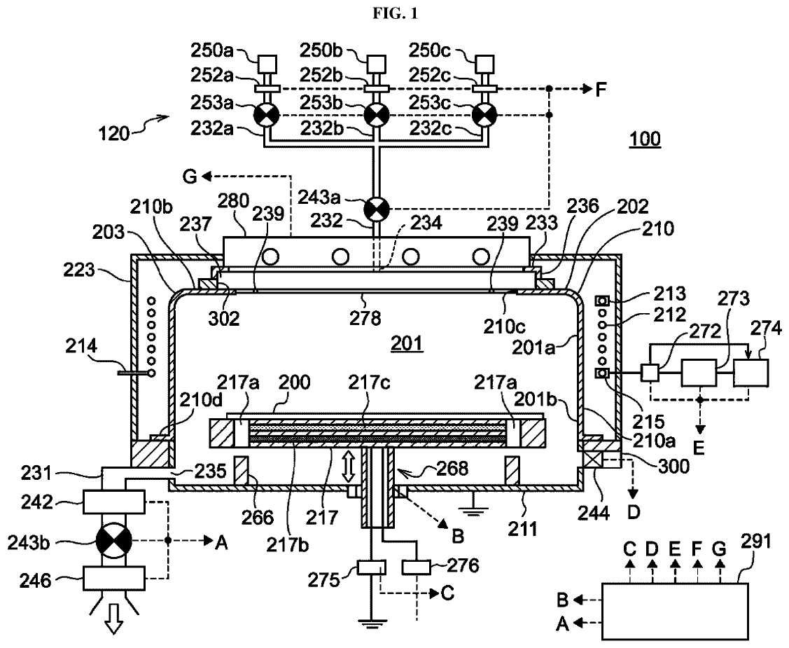

Hereinafter, a configuration of a substrate processing apparatus 100 according to the embodiments of the present disclosure will be described below with reference to FIGS. 1 to 4. The substrate processing apparatus 100 according to the present embodiments is configured to perform an oxidation process by using a plasma mainly on a base (such as an underlying layer) or a film formed on a surface of a substrate 200.

### <Process Chamber>

The substrate processing apparatus 100 includes a process furnace 202 in which the substrate 200 is processed by the plasma. The process furnace 202 is provided with a process vessel 203 constituting a process chamber 201. For example, the process vessel 203 includes a dome-shaped upper vessel 210 and a bowl-shaped lower vessel 211. By covering the lower vessel 211 with the upper vessel 210, the process chamber 201 is defined.

As shown in FIG. 1, the process chamber 201 includes a plasma generation space 201a and a substrate processing space 201b. The plasma generation space 201a is a space corresponding to a range where a resonance coil 212 (which is a coil serving as an electrode) is provided therearound, and is a space in which the plasma is generated. That is, the plasma generation space 201a refers to a space above a lower end of the resonance coil 212 and below an upper end of the resonance coil 212 in the process chamber 201. The substrate processing space 201b is a space communicating with the plasma generation space 201a, is a space in which the substrate 200 is processed. That is, the substrate processing space 201b refers to a space in which the substrate 200 is processed by using the plasma, for example, a space below the lower end of the resonance coil 212.

According to the present embodiments, for example, a diameter of the plasma generation space 201a in a horizontal direction is set to be substantially the same as a diameter of the substrate processing space 201b in the horizontal direction.

For example, configurations constituting the plasma generation space 201a may also be referred to as a “plasma generation chamber”, and configurations constituting the substrate processing space 201b may also be referred to as a “substrate process chamber”.

In addition, the plasma generation space 201a may also be referred to as a “plasma generation region” in the process chamber 201, and the substrate processing space 201b may also be referred to as a “substrate processing region” in the process chamber 201.

As shown in FIG. 1, the upper vessel 210 includes a side wall (which is of a cylindrical shape) 210a and a ceiling 210b. The ceiling 210b is a portion protruding radially inward from an upper end portion of the side wall 210a. An opening 210c is provided (or formed) in a central portion of the ceiling 210b. A transmission window 278 is attached to the opening 210c. The transmission window 278 serves as a light transmission window made of a transparent material. The transmission window 278 is disposed opposite to an upper surface of a susceptor 217 described later.

As shown in FIG. 1, a flange 210d is provided at a lower end portion of the upper vessel 210. The flange 210d is a portion protruding radially outward from a lower end portion of the side wall 210a. The flange 210d is of an annular shape extending along a circumferential direction of the side wall 210a. A manifold 300 of an annular shape is joined to the flange 210d from thereunder. When the manifold 300 is joined to the flange 210d, a gap (portion) between the flange 210d and the manifold 300 is sealed. Further, a seal (for example, an O-ring) may be used to seal the gap between the flange 210d and the manifold 300.

As shown in FIG. 1, the ceiling 210b provided with the opening 210c is a portion protruding radially inward from the upper end portion of the side wall 210a. In other words, the ceiling 210b may be considered as a flange provided at an upper end portion of the upper vessel 210. A manifold 302 of the annular shape is joined to the ceiling 210b from thereabove. When the manifold 302 is joined to the ceiling 210b, a gap (portion) between the ceiling 210b and the manifold 302 is sealed. Further, a seal (for example, an O-ring) may be used to seal the gap between the ceiling 210b and the manifold 302.

For example, the upper vessel 210 may be made of quartz. For example, the lower vessel 211 may be made of aluminum (Al). A gate valve 244 is provided on a lower side of a side wall of the lower vessel 211.

As shown in FIG. 1, the susceptor 217 serving as a substrate mounting table (on which the substrate 200 can be placed) is disposed at a center of a lower portion of the process chamber 201. The susceptor 217 is disposed below the resonance coil 212 in the process chamber 201. Specifically, the susceptor 217 is disposed in the substrate processing space 201b within the process chamber 201.

### <Susceptor>

A susceptor heater 217b serving as a heater (also referred to as a “third heater”) is integrally embedded in the susceptor 217. The susceptor heater 217b is configured to heat the substrate 200 when an electric power is supplied to the susceptor heater 217b through a heater power regulator 276.

The susceptor 217 is electrically insulated from the lower vessel 211. An impedance adjusting electrode 217c is provided in the susceptor 217 so as to further improve a uniformity of a plasma density of the plasma generated on the substrate 200 placed on the susceptor 217. The impedance adjusting electrode 217c is grounded via a variable impedance regulator 275 serving as an impedance adjusting structure.

A susceptor elevator 268 including a driver (which is a driving structure) capable of elevating and lowering the susceptor 217 is provided at the susceptor 217. In addition, through-holes 217a are provided at the susceptor 217, and wafer lift pins 266 are provided at a bottom surface of the lower vessel 211 at locations corresponding to the through-holes 217a. When the susceptor 217 is lowered by the susceptor elevator 268, the wafer lift pins 266 pass through the through-holes 217a. In addition, the driver of the susceptor elevator 268 is controlled by a controller 291 described later. That is, an elevating and lowering operation for the susceptor 217 is controlled by the controller 291. The controller 291 is configured to be capable of controlling the driver of the susceptor elevator 268 such that, when processing the substrate 200 placed on the upper surface (an example of a substrate placing surface) of the susceptor 217, the substrate 200 is located below the plasma generation space 201a.

### <Lamp Heater>

A lamp heater 280 serving as a heater (also referred to as a “second heater”) is provided at a position facing the upper surface of the susceptor 217 in the process chamber 201. The lamp heater 280 is disposed above the process chamber 201, that is, outside the transmission window 278 attached to the upper vessel 210 when viewed from the process chamber 201. The lamp heater 280 is configured to heat the substrate 200 accommodated in the process chamber 201 by radiating (emitting) a light from above the substrate 200 through an outside (that is, an upper side) of the transmission window 278. Specifically, the lamp heater 280 is attached to a central portion of a lid 233. An outer periphery of the lid 233 is joined to the manifold 302. That is, the lid 233 to which the lamp heater 280 is attached is joined to the upper vessel 210 via the manifold 302. A seal (not shown) is disposed between the lid 233 and the manifold 302.

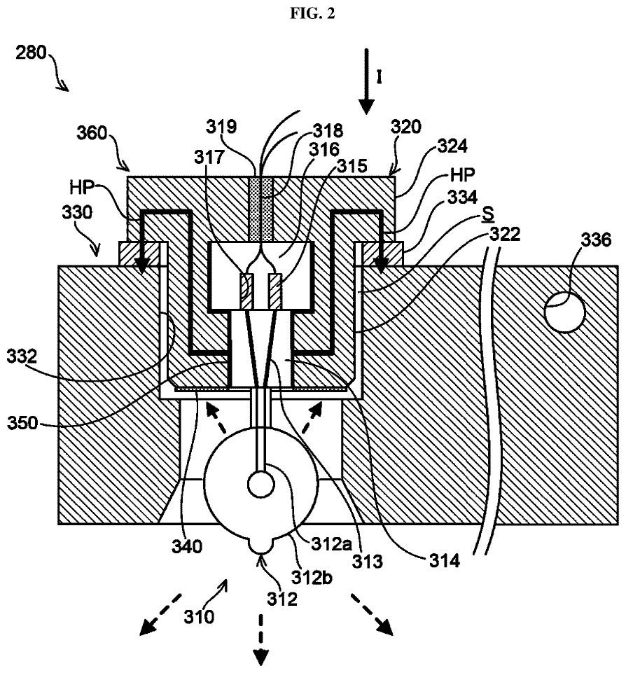

As shown in FIG. 2, the lamp heater 280 includes a heating structure 310 (which is a heater, and also referred to as a “first heater”), a holder 320, a housing 330 and a thermal attenuator (which is a thermal attenuating structure) 340.

As shown in FIG. 2, the heating structure 310 includes at least a lamp 312 and a storage 314. The heating structure 310 may further include a socket 316.

The lamp 312 is configured to be capable of radiating the light to heat the substrate 200 in the process chamber 201. For example, the lamp 312 is a halogen lamp. For example, a halogen gas is sealed in a bulb 312b (which is made of quartz) of the lamp 312. A filament 312a is embedded in the bulb 312b.

The storage 314 is configured to store (or accommodate) a lamp wiring 313 serving as a second wiring connected to the lamp 312. The storage 314 is formed continuously from the bulb 312b to seal the bulb 312b such that halogen gas does not leak out from the bulb 312b. According to the present embodiments, for example, the storage 314 is made of quartz. The storage 314 is further configured to store the lamp wiring 313 electrically connected to the filament 312a. For example, as the lamp wiring 313, a molybdenum foil may be used. The lamp wiring 313 is electrically connected to a plug 315 protruding from the storage 314.

The socket 316 is connected to the storage 314 of the lamp 312, and supplies an electric current to the lamp 312. The socket 316 is provided with a socket hole 317 into which the plug 315 is inserted. The socket 316 also accommodates therein a socket wiring 318 serving as a first wiring. The socket wiring 318 is electrically connected to the socket hole 317.

For example, the socket 316 is made of an insulating material such as ceramic.

By inserting the plug 315 of the lamp 312 into the socket hole 317, the lamp wiring 313 and the socket wiring 318 are electrically connected. That is, the lamp 312 and the socket 316 are electrically connected. By supplying the electric current from an external power supply (not shown) to the socket wiring 318, the electric current is supplied to the lamp wiring 313 via the socket 316.

According to the present embodiments, for example, an electrical connection between the lamp 312 and the socket 316 is established by inserting the plug 315 into the socket hole 317. However, the technique of the present disclosure is not limited to such a configuration. For example, similar to a household incandescent light bulb, the electrical connection may be established by screwing the lamp 312 into the socket 316.

In addition, according to the present embodiments, at least a portion of an outer periphery of each of the storage 314 and the socket 316 is covered by a first structure 322 of the holder 320.

The socket wiring 318 is covered by a protective material 319. For example, as the protective material 319, a glass wool may be used. The socket wiring 318 is in contact with a second structure 324 of the holder 320 via the protective material 319.

For example, the outer periphery of the storage 314 is covered by a heat transfer material 350. The storage 314 is in contact with the first structure 322 of the holder 320 via the heat transfer material 350. The heat transfer material 350 may also cover the outer periphery of the socket 316, as shown in FIG. 2.

In addition, it is sufficient that the heat transfer material 350 is arranged between the storage 314 and the first structure 322 of the holder 320. That is, for example, the heat transfer material 350 may be fixed to an outer peripheral surface of the storage 314 or to an inner peripheral surface of the first structure 322.

A thermal conductivity of the heat transfer material 350 is set to be higher than a thermal conductivity of the thermal attenuator 340. As the heat transfer material 350, for example, an aluminum foil may be used.

As shown in FIG. 2, the holder 320 is a structure configured to hold (or support) the storage 314 and the socket 316 in the heating structure 310. The holder 320 includes the first structure 322 and the second structure 324.

The first structure 322 is a portion of the holder 320 and configured to cover the outer periphery of the storage 314. According to the present embodiments, the first structure 322 covers an entirety of the outer periphery of the storage 314. However, the technique of the present disclosure is not limited to such a configuration. For example, the first structure 322 may cover a part of the outer periphery of the storage 314.

The second structure 324 is a portion of the holder 320 and configured to be in contact with and supported by a support (which is a support structure) 334 of the housing 330. Specifically, the second structure 324 is a portion protruding outward from a location of the first structure 322 opposite to the lamp 312, and is a portion supported by the support 334 of the housing 330. The second structure 324 is provided continuously with the first structure 322. That is, the second structure 324 and the first structure 322 are integrated together.

The first structure 322 of the holder 320 is inserted in a non-contact state (that is, without being contacted) into an insertion structure 332 (which is described later) of the housing 330. Specifically, an outer diameter of the first structure 322 is set to be smaller than an inner diameter of the insertion structure 332, and a gap S is provided (or formed) between an outer peripheral surface of the first structure 322 and an inner peripheral surface of the insertion structure 332. The gap S is provided along an insertion direction of the first structure 322 of the holder 320 into the insertion structure 332. The insertion direction of the first structure 322 into the insertion structure 332 is a direction indicated by an arrow “I” in FIG. 2.

In addition, the first structure 322 of the holder 320 is configured to be capable of absorbing the heat of the storage 314 and the socket 316. The holder 320 is made of a material whose thermal conductivity is high. For example, as the material whose thermal conductivity is high, aluminum may be used. According to the present embodiments, for example, the holder 320 is made of aluminum.

As shown in FIG. 2, the housing 330 is a base structure (base portion) of the lamp heater 280, and is provided above the process chamber 201. A lamp module 360 (which is described later) is attached to the housing 330. The housing 330 includes the insertion structure 332 and the support 334. According to the present embodiments, for example, a plurality of lamp modules including the lamp module 360 may be attached to the housing 330. Hereinafter, the plurality of lamp modules including the lamp module 360 may also be referred to as “lamp modules 360”.

The insertion structure 332 is a portion of the housing 330. As described above, the first structure 322 of the holder 320 is inserted into the insertion structure 332 in the non-contact state. Specifically, the insertion structure 332 is a through-hole provided in the housing 330. When the holder 320 is inserted into the insertion structure 332, the gap S (which is of an annular shape) is provided between the outer peripheral surface of the first structure 322 and the inner peripheral surface of the insertion structure 332.

One or both of the outer peripheral surface of the first structure 322 of the holder 320 and the inner peripheral surface of the insertion structure 332 may be configured such that a thermal emissivity thereof is set to be higher than that of a location of the first structure 322 where the thermal attenuator 340 is provided. Specifically, One or both of the outer peripheral surface of the first structure 322 and the inner peripheral surface of the insertion structure 332 may be anodized (that is, may be alumite-treated).

The support 334 is a portion of the housing 330 and configured to support the second structure 324 of the holder 320. Specifically, the support 334 is an annular portion provided on a periphery of the insertion structure 332. The support 334 may be provided integrally with the housing 330, or may be configured by fixing an annular structure onto the periphery of the insertion structure 332. According to the present embodiments, for example, the support 334 is configured by fixing the annular structure onto the periphery of the insertion structure 332.

According to the present embodiments, for example, the second structure 324 of the holder 320 is attached to the housing 330 by a screw (not shown) via the support 334. In addition, when the holder 320 is attached to the housing 330, the first structure 322 is inserted into the insertion structure 332 in the non-contact state.

Further, a heat absorption amount by the support 334 is set to be greater than a heat absorption amount by the thermal attenuator 340. Specifically, the housing 330 including the support 334 is made of a material whose thermal conductivity is higher than that of the thermal attenuator 340. According to the present embodiments, for example, similar to the holder 320, the housing 330 including the support 334 is made of aluminum.

For example, a coolant flow path 336 through which a coolant flows may be further provided inside the housing 330.

As shown in FIG. 2, the thermal attenuator 340 is provided at a location of the first structure 322 of the holder 320 facing the lamp 312, is configured to be capable of attenuating the heat generated by the light radiated (emitted) from the lamp 312 to suppress a heat transfer (heat movement) to the holder 320, the lamp wiring 313, and the socket wiring 318. Specifically, by attenuating the light radiated from the lamp 312, the thermal attenuator 340 is configured to attenuate the heat generated by the light and to suppress an increase in a temperature of each of the holder 320, the lamp wiring 313 and the socket wiring 318. In addition, by attenuating the heat generated by the light, thermal attenuator 340 is configured to be capable of providing (or forming) a heat conduction path HP. Thereby, the heat from the storage 314 is conducted to the housing 330 along the heat conduction path HP via the first structure 322, the second structure 324 and the support 334.

The thermal attenuator 340 is provided at an end portion of the first structure 322 adjacent to the lamp 312, that is, a lower end portion of the first structure 322. The thermal attenuator 340 may be formed by processing a surface of the end portion of the first structure 322, or may be provided by attaching a structure serving as the thermal attenuator 340 to the end portion of the first structure 322. Alternatively, the thermal attenuator 340 may be provided by applying a material capable of attenuating the heat.

For example, a plurality of combinations of the heating structure 310, the holder 320 and the thermal attenuator 340 are attached to the housing 330. That is, a plurality of heating structures including the heating structure 310 are provided, and a plurality of holders including the holder 320 are provided corresponding to the plurality of heating structures, respectively. Further, a plurality of thermal attenuators including the thermal attenuator 340 are provided corresponding to the plurality of heating structures and the plurality of holders. Hereinafter, the plurality of heating structures including the heating structure 310 may also be simply referred to as “heating structures 310”, the plurality of holders including the holder 320 may also be simply referred to as “holders 320”, and the plurality of thermal attenuators including the thermal attenuator 340 may also be simply referred to as “thermal attenuators 340”. A difference in thermal attenuation rates (also referred to as a “thermal decay rates”) of the thermal attenuators 340 respectively provided in the holders 320 in the combinations may be set to be within a predetermined range. According to the present embodiments, for example, the thermal attenuators 340 in the combinations may be configured such that their thermal attenuation rates are all the same (substantially all the same).

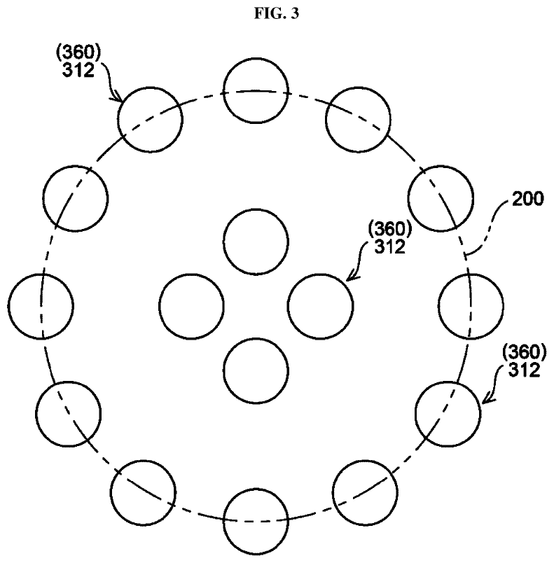

In addition, as in a manner shown in FIG. 3, the plurality of combinations of the heating structure 310, the holder 320 and the thermal attenuator 340 are arranged circumferentially around the substrate 200 in the horizontal direction while the substrate 200 is supported in the process chamber 201. According to the present embodiments, for example, the plurality of combinations of the heating structure 310 and the holder 320 are arranged circumferentially around the substrate 200 at equal intervals. In addition, at least the thermal attenuation rates of the thermal attenuators 340 respectively provided on the holders 320 arranged on the same circle (circumference) may be set to be the same (substantially the same). For example, as in a manner shown in FIG. 3, when the holders 320 are arranged on an outer circle and an inner circle, the thermal attenuation rates of the thermal attenuators 340 provided at the holders 320 arranged on the outer circle may be set to be different from the thermal attenuation rates of the thermal attenuators 340 related to the holders 320 arranged on the inner circle.

According to the present embodiments, the lamp module 360 is constituted by the heating structure 310, the holder 320 and the thermal attenuator 340. In addition, the plurality of lamp modules 360 are attached to a plurality of insertion structures including the insertion structure 332 provided in the housing 330, respectively. Hereinafter, the plurality of insertion structures including the insertion structure 332 may also be simply referred to as “insertion structures 332”.

The holder 320 of the present embodiments may be configured by a plurality of structures. For example, the holder 320 may be configured by assembling two holder halves (which are vertically split).

### <Gas Supplier>

A gas supplier (which is a gas supply structure or a gas supply system) 120 through which a process gas is supplied into the process vessel 203 is configured as follows.

A gas supply head 236 is provided above the process chamber 201, that is, on an upper portion of the upper vessel 210. The gas supply head 236 includes the cap-shaped lid 233, a gas inlet port 234, a buffer chamber 237 and a gas outlet port 239, and is configured such that a reactive gas (that is the process gas) is capable of being supplied into the process chamber 201 through the gas supply head 236. The gas outlet port 239 is provided in the transmission window 278.

A downstream end of an oxygen-containing gas supply pipe 232a through which an oxygen-containing gas is supplied, a downstream end of a hydrogen-containing gas supply pipe 232b through which a hydrogen-containing gas is supplied and a downstream end of an inert gas supply pipe 232c through which an inert gas is supplied are connected to a junction pipe (which is a gas supply pipe) 232 of the gas inlet port 234 so as to be conjoined with one another. The oxygen-containing gas supply pipe 232a may also be simply referred to as a “gas supply pipe 232a”. The hydrogen-containing gas supply pipe 232b may also be simply referred to as a “gas supply pipe 232b”. The inert gas supply pipe 232c may also be simply referred to as a “gas supply pipe 232c”.

An oxygen-containing gas supply source 250a, a mass flow controller (MFC) 252a serving as a flow rate controller and a valve 253a serving as an opening/closing valve are sequentially provided at the gas supply pipe 232a in this order from an upstream side to a downstream side of the gas supply pipe 232a in a gas flow direction.

A hydrogen-containing gas supply source 250b, an MFC 252b and a valve 253b are sequentially provided at the gas supply pipe 232b in this order from an upstream side to a downstream side of the gas supply pipe 232b in the gas flow direction.

An inert gas supply source 250c, an MFC 252c and a valve 253c are sequentially provided at the gas supply pipe 232c in this order from an upstream side to a downstream side of the gas supply pipe 232c in the gas flow direction.

A valve 243a is provided at the junction pipe 232 at a downstream side of a location where the gas supply pipe 232a, the gas supply pipe 232b and the gas supply pipe 232c join. The junction pipe 232 is connected to the gas inlet port 234. By opening and closing the valves 253a, 253b, 253c and 243a, it is possible to adjust flow rates of the oxygen-containing gas, the hydrogen-containing gas and the inert gas by the MFCs 252a, 252b and 252c, respectively. In addition, it is configured such that the process gas such as the oxygen-containing gas, the hydrogen-containing gas and the inert gas is capable of being supplied into the process chamber 201 through the gas supply pipe 232a, the gas supply pipe 232b and the gas supply pipe 232c.

The gas supplier (which is the gas supply system or the gas supply structure) 120 according to the present embodiments is constituted mainly by the gas supply pipe 232a, the gas supply pipe 232b, the gas supply pipe 232c, the MFCs 252a, 252b and 252c and the valves 253a, 253b, 253c and 243a.

### <Exhauster>

A gas exhaust port 235 through which the reactive gas is exhausted from an inside (inner portion) of the process chamber 201 is provided on the side wall of the lower vessel 211. An upstream end of a gas exhaust pipe 231 is connected to the gas exhaust port 235. An APC (Automatic Pressure Controller) valve 242 serving as a pressure regulator (pressure adjusting structure), a valve 243b serving as an opening/closing valve and a vacuum pump 246 serving as a vacuum exhaust apparatus are sequentially provided at the gas exhaust pipe 231 in this order from an upstream side to a downstream side of the gas exhaust pipe 231 in the gas flow direction.

An exhauster (which is an exhaust structure or an exhaust system) according to the present embodiments is constituted mainly by the gas exhaust port 235, the gas exhaust pipe 231, the APC valve 242 and the valve 243b. In addition, the exhauster may further include the vacuum pump 246.

### <Plasma Generator>

The resonance coil 212 of a helical shape is disposed around an outer periphery of the process chamber 201 (that is, around an outer portion of the side wall 210a of the upper vessel 210) so as to surround the process chamber 201. In other words, the resonance coil 212 is disposed so as to surround an outer periphery (outer periphery of the plasma generation chamber) of a portion (region) of the process vessel 203 (that is, the upper vessel 210) corresponding to the plasma generation space 201a.

An RF (Radio Frequency) sensor 272, a high frequency power supply 273 and a matcher (which is a matching structure) 274 configured to perform an impedance matching or an output frequency matching for the high frequency power supply 273 are connected to the resonance coil 212. The resonance coil 212 extends along an outer peripheral surface of the process vessel 203 while spaced apart from the outer peripheral surface of the process vessel 203, and is configured to generate an electromagnetic field in the process vessel 203 when a high frequency power (RF power) is supplied to the resonance coil 212. That is, the resonance coil 212 according to the present embodiments may be constituted by an inductively coupled plasma (ICP) type electrode.

The high frequency power supply 273 is configured to supply the high frequency power (RF power) to the resonance coil 212. The RF sensor 272 is provided at an output side of the high frequency power supply 273. The RF sensor 272 is configured to monitor information of a traveling wave or a reflected wave of the high frequency (RF) power supplied from the high frequency power supply 273. An electric power of the reflected wave monitored by the RF sensor 272 is inputted to the matcher 274, and the matcher 274 is configured to adjust an impedance of the high frequency power supply 273 or a frequency of the RF power output from the high frequency power supply 273 so as to minimize the reflected wave based on the information of the reflected wave inputted from the RF sensor 272.

A winding diameter, a winding pitch and the number of winding turns of the resonance coil 212 are set such that the resonance coil 212 resonates at a constant wavelength to form a standing wave of a predetermined wavelength.

Both ends of the resonance coil 212 are electrically grounded. At least one end of the resonance coil 212 is grounded via a movable tap 213 in order to fine-tune an electrical length of the resonance coil 212, and the other end of the resonance coil 212 is grounded via a fixed ground 214. Further, a position of the movable tap 213 may be adjusted in order for resonance characteristics of the resonance coil 212 to become approximately the same as those of the high frequency power supply 273. In addition, in order to fine-tune the impedance of the resonance coil 212, a power feeder is constituted by a movable tap 215 provided between the grounded both ends of the resonance coil 212.

A shield plate 223 is provided to shield an inside thereof from an electric field outside of the resonance coil 212. For example, the shield plate 223 is made of a conductive material such as an aluminum alloy, and is of a cylindrical shape.

A plasma generator (which is a plasma generating structure) according to the present embodiments is constituted mainly by the resonance coil 212, the RF sensor 272 and the matcher 274. The plasma generator may further include the high frequency power supply 273.

According to the present embodiments, for example, the resonance coil 212 (which is the ICP type electrode) is used as the electrode for generating the electromagnetic field in the process chamber 201 (that is, in the plasma generation space 201a). However, the technique of the present disclosure is not limited to such a configuration. For example, a modified magnetron type (MMT) electrode of a cylindrical shape may be used as the resonance coil 212.

### <Controller>

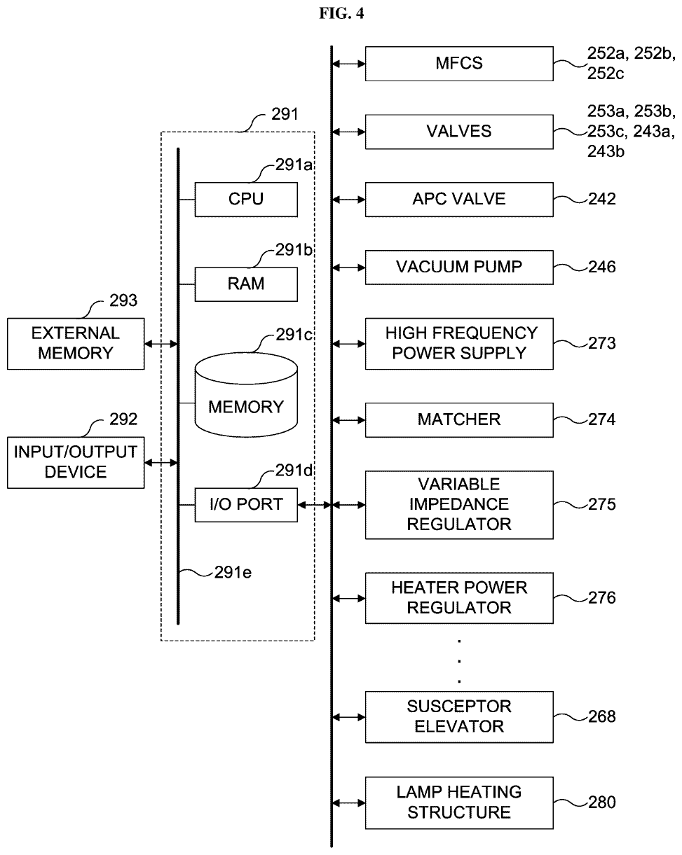

As shown in FIG. 4, the controller 291 serving as the control structure (control apparatus) of the substrate processing apparatus 100 is constituted by a computer including a CPU (Central Processing Unit) 291a, a RAM (Random Access Memory) 291b, a memory 291c and an I/O port 291d. The RAM 291b, the memory 291c and the I/O port 291d are configured to be capable of exchanging data with the CPU 291a through an internal bus 291e. For example, an input/output device 292 constituted by a component such as a touch panel and a display may be connected to the controller 291.

The memory 291c may be embodied by a component such as a flash memory and a hard disk drive (HDD). For example, a control program configured to control operations of the substrate processing apparatus 100 and a process recipe in which information such as procedures and conditions of a substrate processing described later is stored may be readably stored in the memory 291c. The process recipe is obtained by combining steps (procedures) of the substrate processing described later such that the controller 291 can execute the steps to acquire a predetermined result, and functions as a program. Hereinafter, the process recipe and the control program may be collectively or individually referred to as a “program”. Thus, in the present disclosure, the term “program” may refer to the process recipe alone, may refer to the control program alone, or may refer to both of the process recipe and the control program. Further, the RAM 291b functions as a memory area (work area) where a program or data read by the CPU 291a is temporarily stored.

The I/O port 291d is electrically connected to the components described above such as the MFCs 252a, 252b and 252c, the valves 253a, 253b and 253c, the valves 243a and 243b, the gate valve 244, the APC valve 242, the vacuum pump 246, the RF sensor 272, the high frequency power supply 273, the matcher 274, the susceptor elevator 268, the variable impedance regulator 275 and the heater power regulator 276.

The CPU 291a is configured to be capable of reading and executing the control program stored in the memory 291c, and capable of reading the process recipe stored in the memory 291c in accordance with an instruction such as an operation command inputted via the input/output device 292. In addition, the CPU 291a is configured to be capable of controlling various operations, in accordance with the read process recipe, such as an operation of adjusting an opening degree of the APC valve 242, an opening and closing operation of the valve 243b and a start and stop of the vacuum pump 246 via the I/O port 291d and a signal line “A”. In addition, the CPU 291a is further configured to be capable of controlling various operations, in accordance with the read process recipe, such as an elevating and lowering operation of the susceptor elevator 268 via the I/O port 291d and a signal line “B”. In addition, the CPU 291a is further configured to be capable of controlling various operations, in accordance with the read process recipe, such as a power supply amount adjusting operation (temperature adjusting operation) to the susceptor heater 217b by the heater power regulator 276 and an impedance value adjusting operation by the variable impedance regulator 275 via the I/O port 291d and a signal line “C”. In addition, the CPU 291a is further configured to be capable of controlling various operations, in accordance with the read process recipe, such as an opening and closing operation of the gate valve 244 via the I/O port 291d and a signal line “D”. In addition, the CPU 291a is further configured to be capable of controlling various operations, in accordance with the read process recipe, such as controlling operations for the RF sensor 272, the matcher 274 and the high frequency power supply 273 via the I/O port 291d and a signal line “E”. In addition, the CPU 291a is further configured to be capable of controlling various operations, in accordance with the read process recipe, such as flow rate adjusting operations for various gases by the MFCs 252a, 252b and 252c and opening and closing operations of the valves 253a, 253b, 253c and 243a via the I/O port 291d and a signal line “F”. In addition, the CPU 291a may also be further configured to be capable of controlling various operations of components (of the substrate processing apparatus 100) other than those mentioned above.

The controller 291 may be embodied by installing the above-mentioned program stored in an external memory 293 (for example, a magnetic tape, a magnetic disk such as a flexible disk and a hard disk, an optical disk such as a CD and a DVD, a magneto-optical disk such as an MO and a semiconductor memory such as a USB memory and a memory card) into the computer. The memory 291c or the external memory 293 may be embodied by a non-transitory computer readable recording medium. Hereafter, the memory 291c and the external memory 293 may be collectively or individually referred to as a “recording medium”. Thus, in the present disclosure the term “recording medium” may refer to the memory 291c alone, may refer to the external memory 293 alone, or may refer to both of the memory 291c and the external memory 293. The program may be provided to the computer without using the external memory 293. For example, the program may be supplied to the computer using a communication structure such as the Internet and a dedicated line.

### (2) Substrate Processing

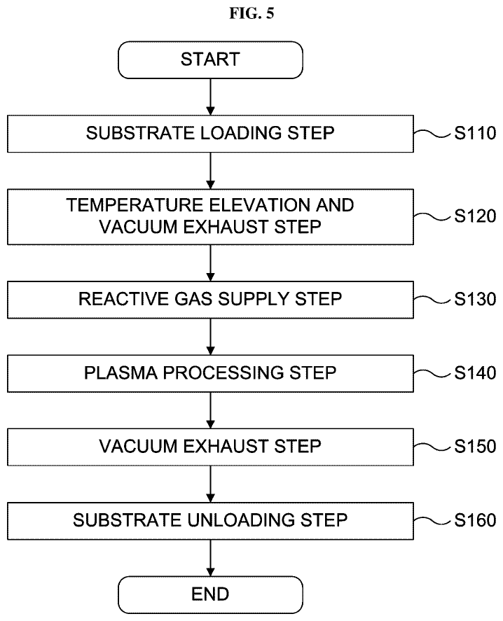

Subsequently, the substrate processing according to the embodiments of the present disclosure will be described mainly with reference to FIG. 5. FIG. 5 is a flow chart schematically illustrating the substrate processing according to the present embodiments. The substrate processing according to the present embodiments (which is a part of a manufacturing process of the semiconductor device such as a flash memory) is performed by using the substrate processing apparatus 100 described above. In the following description, operations of the components constituting the substrate processing apparatus 100 are controlled by the controller 291.

Further, a silicon (Si) layer is formed in advance on the surface of the substrate 200 to be processed by the substrate processing according to the present embodiments. According to the present embodiments, for example, an oxidation process serving as a process using the plasma is performed with respect to the silicon layer.

### <Substrate Loading Step S110>

First, the susceptor 217 is lowered to a transfer position of the substrate 200 by the susceptor elevator 268 such that the wafer lift pins 266 pass through the through-holes 217a of the susceptor 217. Subsequently, the gate valve 244 is opened, and the substrate 200 is loaded (transferred) into the process chamber 201 using a substrate transfer structure (not shown) from a vacuum transfer chamber (not shown) provided adjacent to the process chamber 201. The substrate 200 loaded into the process chamber 201 is placed on and supported by the wafer lift pins 266 (which protrude from the surface of the susceptor 217) in a horizontal orientation. Then, by elevating the susceptor 217 using the susceptor elevator 268, the substrate 200 is placed on and supported by the upper surface of the susceptor 217.

### <Temperature Elevation and Vacuum Exhaust Step S120>

Subsequently, a temperature of the substrate 200 loaded into the process chamber 201 is elevated. In the present step, the susceptor heater 217b is heated in advance. By turning on the lamp heater 280, it is possible to elevate the temperature of the substrate 200 held on (that is, supported by) the susceptor 217. In such a state, most of the light emitted from the lamp heater 280 capable of heating the substrate 200 is reflected within the process chamber 201 without being absorbed by the upper vessel 210, as described below. That is, since most of the light emitted from the lamp heater 280 is absorbed by the substrate 200. Thereby, it is possible to efficiently heat the substrate 200. Further, while the temperature of the substrate 200 is being elevated, the vacuum pump 246 vacuum-exhausts the inside of the process chamber 201 through the gas exhaust pipe 231 such that a pressure (inner pressure) of the process chamber 201 reaches and is maintained at a predetermined pressure. The vacuum pump 246 is continuously operated at least until a substrate unloading step S160 described later is completed.

### <Reactive Gas Supply Step S130>

Subsequently, as a supply of the reactive gas (process gas), a supply of the oxygen-containing gas and a supply of the hydrogen-containing gas into the process chamber 201 are started. Specifically, the valve 253a and the valve 253b are opened to start the supply of the oxygen-containing gas and the supply of the hydrogen-containing gas into the process chamber 201 while flow rates of the oxygen-containing gas and the hydrogen-containing gas are adjusted by the MFCs 252a and 252b, respectively.

Further, for example, an exhaust of the inside of the process chamber 201 is controlled by adjusting the opening degree of the APC valve 242 such that the inner pressure of the process chamber 201 reaches and is maintained at a predetermined pressure. While appropriately exhausting the inside of the process chamber 201 in a manner described above, the oxygen-containing gas and the hydrogen-containing gas are continuously supplied into the process chamber 201 until a plasma processing step S140 described later is completed.

### <Plasma Processing Step S140>

When the inner pressure of the process chamber 201 is stabilized, an application of the high frequency power to the resonance coil 212b from the high frequency power supply 273 is started. Thereby, a high frequency electric field is formed (or provided) in the plasma generation space 201a to which the oxygen-containing gas and the hydrogen-containing gas are supplied. By forming the high frequency electric field, a donut-shaped induction plasma whose plasma density is the highest at a height position corresponding to an electrical midpoint of the resonance coil 212 in the plasma generation space 201a can be excited. The process gas (that is, the oxygen-containing gas and the hydrogen-containing gas in plasma states) is excited into a plasma state and dissociates. As a result, reactive species such as oxygen radicals containing oxygen (oxygen active species), oxygen ions, hydrogen radicals containing hydrogen (hydrogen active species) and hydrogen ions can be generated.

The radicals generated by the induction plasma and the ions (which are not accelerated) are uniformly supplied into the surface of the substrate 200 placed on the susceptor 217 in the substrate processing space 201b. Then, the radicals and the ions supplied as described above react uniformly with the silicon layer formed on the surface of the substrate 200. Thereby, the silicon layer is modified into a silicon oxide layer whose step coverage is enhanced.

After a predetermined process time has elapsed, the output of the high frequency power from the high frequency power supply 273 is stopped to stop a plasma discharge in the process chamber 201. In addition, the valve 253a and the valve 253b are closed to stop the supply of the oxygen-containing gas and the supply of the hydrogen-containing gas into the process chamber 201. Thereby, the plasma processing step S140 is completed.

### <Vacuum Exhaust Step S150>

After the supply of the oxygen-containing gas and the supply of the hydrogen-containing gas are stopped, the inside of the process chamber 201 is vacuum-exhausted through the gas exhaust pipe 231. Thereby, a gas such as the oxygen-containing gas and the hydrogen-containing gas and an exhaust gas generated from a reaction therebetween in the process chamber 201 can be exhausted out of the process chamber 201. Thereafter, the opening degree of the APC valve 242 is adjusted such that the inner pressure of the process chamber 201 is adjusted to the same pressure as that of the vacuum transfer chamber (not shown) provided adjacent to the process chamber 201. The vacuum transfer chamber serves as a destination to which the substrate 200 is to be transferred.

### <Substrate Unloading Step S160>

After the inner pressure of the process chamber 201 is adjusted to a predetermined pressure, the susceptor 217 is lowered to the transfer position of the substrate 200 until the substrate 200 is supported by the wafer lift pins 266. Then, the gate valve 244 is opened, and the substrate 200 is transferred (unloaded) out of the process chamber 201 by using the substrate transfer structure (not shown). Thereby, the substrate processing according to the present embodiments is completed.

According to the present embodiments, it is possible to obtain one or more of the following effects.

According to the present embodiments, since the heat generated by the light emitted from the lamp 312 is attenuated by the thermal attenuator 340 provided in the first structure 322 of the holder 320, it is possible to suppress an excessive increase in a temperature of the first structure 322. Therefore, a relationship of temperatures of the respective structures can be set such that a temperature of the storage 314 is greater than the temperature of the first structure 322, the temperature of the first structure 322 is greater than a temperature of the second structure 324, the temperature of the second structure 324 is greater than a temperature of the support 334, and the temperature of the support 334 is greater than a temperature of the housing 330. Therefore, the heat of the lamp wiring 313 accompanying a light emission of the lamp 312 is transferred (moves) to the first structure 322 of the holder 320 via the storage 314. The heat transferred to the first structure 322 of the holder 320 is transferred to the second structure 324. The heat transferred to the second structure 324 is dissipated from the second structure 324 to the housing 330 via the support 334. That is, the heat conduction path HP mentioned above is formed, via which the heat passes from the storage 314 through the first structure 322, the second structure 324, the support 334 and the housing 330. According to the present embodiments, since the housing 330 is cooled by the coolant flow path 336, it is possible to efficiently cool the lamp wiring 313.

In addition, according to the present embodiments, the heat generated by the light emitted from lamp 312 is attenuated by the thermal attenuator 340 provided in the first structure 322 of the holder 320. Therefore, according to the present embodiments, for example, it is possible to suppress the increase in the temperature of the first structure 322 as compared with a case where the heat generated by the light emitted from lamp 312 is transferred to the first structure 322 without being attenuated.

In addition, according to the present embodiments, the first structure 322 of the holder 320 is inserted into the insertion structure 332 in a non-contact state, and in such a state, the second structure 324 of the holder 320 is supported by the support 334 of the housing 330. Therefore, according to the present embodiments, as compared with a case where the first structure 322 is inserted into the insertion structure 332 in a contacting state, a friction is less likely to occur between the first structure 322 and the insertion structure 332. Thereby, it is possible to easily insert and remove the first structure 322 into and from the insertion structure 332.

As described above, according to the present embodiments, it is possible to easily insert and remove the holder 320 of the lamp 312 into and from the insertion structure 332 of the housing 330, while suppressing the increase in the temperature of the holder 320 when the lamp 312 is emitting the light.

According to the present embodiments, the heat of the socket wiring 318 accompanying the light emission from the lamp 312 is transferred from the first structure 322 of the holder 320 to the second structure 324 and the support 334 of the housing 330 via the socket 316, and dissipated. Thereby, it is possible to suppress the increase in the temperature of the holder 320 when the lamp 312 is emitting the light.

According to the present embodiments, when the lamp wiring 313 is configured to contact the second structure 324 of the holder 320 via the protective material 319, it is possible to directly transfer the heat of the socket wiring 318 to the second structure 324. This allows the socket wiring 318 to be efficiently cooled.

According to the present embodiments, the gap S is formed (provided) between the outer peripheral surface of the first structure 322 of the holder 320 and the inner peripheral surface of the insertion structure 332. Thereby, for example, as compared with a case where other materials are filled into the gap S, it is possible to easily insert and remove the holder 320 of the lamp 312 into and from the insertion structure 332 of the housing 330.

According to the present embodiments, the gap S is formed along the insertion direction I of the first structure 322 of the holder 320 into the insertion structure 332. Thereby, it is possible for the first structure 322 to dissipate the heat uniformly in the insertion direction I of the first structure 322 of the holder 320 into the insertion structure 332.

According to the present embodiments, the heat in the storage 314 is transferred to the first structure 322 via the heat transfer material 350. Thereby, it is possible to efficiently dissipate the heat of the lamp wiring 313 in the storage 314.

According to the present embodiments, the thermal attenuator 340 is provided at the end portion of the first structure 322 adjacent to the lamp 312. Thereby, the heat from the light emitted from the lamp 312 is less likely to be transmitted from the first structure 322 to the second structure 324 of the holder 320.

According to the present embodiments, when one or both of the outer peripheral surface of the first structure 322 of the holder 320 and the inner peripheral surface of the insertion structure 332 are alumite-treated, the thermal emissivity thereof is higher than that of the location of the first structure 322 where the thermal attenuator 340 is provided, and a heat transfer amount by the radiation increases.

According to the present embodiments, when the thermal emissivity of one or both of the outer peripheral surface of the first structure 322 of the holder 320 and the inner peripheral surface of the insertion structure 332 is set to be higher than that of the location where the thermal attenuator 340 is provided, it is possible to set the thermal emissivity to be higher than that of the location of the first structure 322 where the thermal attenuator 340 is provided, and it is possible to increase the heat transfer amount by the radiation.

According to the present embodiments, when the heat absorption amount by the support 334 is set to be greater than the heat absorption amount by the thermal attenuator 340, it is possible to efficiently transfer the heat (which is transferred from the first structure 322 to the second structure 324 of the holder 320) to the support 334.

According to the present embodiments, when the thermal conductivity of the heat transfer material 350 is set to be higher than the thermal conductivity of the thermal attenuator 340, it is possible to efficiently transfer the heat of the storage 314 from the first structure 322 to the support 334 via the second structure 324.

According to the present embodiments, when the difference in the thermal attenuation rate of each of the thermal attenuators 340 is set to be within a predetermined range, it is possible to suppress a progression of deterioration of a particular wiring. In such a case, it is possible to uniformly heat the substrate 200.

According to the present embodiments, when the thermal attenuation rates of the thermal attenuators 340 are set to be the same (substantially the same), it is possible to uniformize (that is, substantially uniformize) a degree of the deterioration. Thereby, it is possible to uniformly heat the substrate 200.

According to the present embodiments, by setting the thermal attenuation rates of the thermal attenuators 340 respectively provided on the holders 320 and arranged circumferentially around the substrate 200 to be the same (substantially the same), it is possible to uniformize a heating capacity around the substrate 200. For example, in a substrate processing apparatus where the gas is supplied to the substrate 200 from above and is exhausted through a periphery of the substrate 200, variations may occur in the substrate processing in a concentric manner. For example, there may be variations in the substrate processing between a center of the substrate 200 and the periphery of the substrate 200. Therefore, by using the above-described configurations of the present embodiments, it is possible to control the heating of the substrate 200 at least on a peripheral basis (circumferential basis), and it is also possible to absorb the variations in the substrate processing. For example, the center of the substrate 200 may be heated strongly, and the periphery of the substrate 200 may be heated weakly.

### <Other Embodiments of Present Disclosure>

For example, the embodiments mentioned above are described by way of an example in which the process chamber 201 constituted by the process vessel 203 includes the plasma generation chamber and the substrate processing chamber (that is, the plasma generation chamber and the substrate processing chamber are configured as an internal space of the same process vessel 203). However, the technique of the present disclosure is not limited thereto. For example, the plasma generation chamber and the substrate processing chamber may be configured as separate vessels. Further, for example, the embodiments mentioned above are described by way of an example in which the upper vessel 210 serves as an example of the process vessel in the present disclosure. However, the technique of the present disclosure is not limited thereto. For example, when the process vessel 203 is configured as an integrally molded product, the process vessel 203 serves as an example of the process vessel in the present disclosure.

For example, the embodiments mentioned above are described by way of an example in which the oxidation process is performed onto the surface of the substrate 200 by using the plasma. However, the technique of the present disclosure may also be applied to a nitridation process using a nitrogen-containing gas as the process gas. For example, the technique of the present disclosure is not limited to the oxidation process and the nitridation process, and may also be applied to other processing techniques of processing the substrate by using the plasma. For example, the technique of the present disclosure may be applied to a process such as a modification process onto the film formed on the surface of the substrate, a doping process, a reduction process of an oxide film, an etching process with respect to the film and an ashing process for a photoresist, which are performed by using the plasma.

While the technique of the present disclosure is described in detail by way of the embodiments and the modified examples described above, the technique of the present disclosure is not limited thereto. It will be apparent to those skilled in the art that the technique of the present disclosure may be modified in various ways without departing from the scope thereof.

According to some embodiments of the present disclosure, it is possible to easily insert and remove the holder (which is configured to hold a heat lamp) into and from the insertion structure of the housing, while suppressing the increase in the temperature of the holder when the heat lamp is in operation.

What is claimed is:

1. A heating method comprising:
(a) loading a substrate into a process chamber;
(b) operating a heater comprising a lamp capable of radiating a light to heat the substrate and a storage capable of storing a wiring connected to the lamp; attenuating a heat generated by the light radiated from the lamp by a thermal attenuator provided at a location of a first structure facing the lamp, wherein the first structure is provided at a holder and configured to cover an outer periphery of the storage; and forming a heat conduction path of a heat of the storage to a housing via the first structure, a second structure provided at the holder and a support of the housing, wherein the second structure protrudes outward from another location of the first structure opposite to the lamp, and wherein the housing is provided above the process chamber and comprises an insertion structure into which the first structure is inserted in a non-contact state and the support configured to support the second structure; and
(c) heating the substrate by the heater.

2. The heating method of claim 1, wherein the heater further comprises a socket capable of accommodating a first wiring therein and capable of being connected to the storage,
wherein at least a part of an outer periphery of the socket is covered by the first structure,
wherein the first wiring is electrically connected to a second wiring serving as the wiring when the first wiring is connected to the storage, and
wherein a heat in the socket is conducted to the housing via the heat conduction path.

3. The heating method of claim 2, wherein the second wiring is covered by a protective material in contact with the second structure, and
wherein a heat of the second wiring is conducted to the housing via the protective material and the second structure.

4. The heating method of claim 1, wherein, in (b), the heater is operated when a gap is provided between an outer peripheral surface of the first structure and an inner peripheral surface of the insertion structure.

5. The heating method of claim 4, wherein the gap is provided along an insertion direction of the first structure into the insertion structure.

6. The heating method of claim 4, wherein, in (b), the heater is operated when one or both of the outer peripheral surface of the first structure and the inner peripheral surface of the insertion structure are alumite-treated.

7. The heating method of claim 4, wherein, in (b), the heater is operated when a thermal emissivity of one or both of the outer peripheral surface of the first structure and the inner peripheral surface of the insertion structure are set to be higher than that of the location of the first structure where the thermal attenuator is provided.

8. The heating method of claim 1, wherein the outer periphery of the storage is covered by a heat transfer material, and
wherein, in (b), the heater is operated when the storage is in contact with the first structure via the heat transfer material.

9. The heating method of claim 8, wherein, in (b), the heater is operated when a thermal conductivity of the heat transfer material is set to be higher than a thermal conductivity of the thermal attenuator.

10. The heating method of claim 1, wherein, in (b), the heater is operated when the thermal attenuator is provided at an end portion of the first structure adjacent to the lamp.

11. The heating method of claim 1, wherein, in (b), the heater is operated when a heat absorption amount by the support is set to be greater than a heat absorption amount by the thermal attenuator.

12. The heating method of claim 1, wherein a plurality of combinations of the heater, the holder and the thermal attenuator are provided at the housing, and
wherein, in (b), the heater is operated when a difference in a thermal attenuation rate between thermal attenuators in the combinations is set to be within a predetermined range.

13. The heating method of claim 1, wherein a plurality of combinations of the heater, the holder and the thermal attenuator are provided at the housing, and
wherein, in (b), the heater is operated when thermal attenuation rates of thermal attenuators in the combinations are substantially equal.

14. The heating method of claim 1, wherein a plurality of combinations of the heater, the holder and the thermal attenuator are provided at the housing in a manner that the combinations are arranged circumferentially around the substrate in a horizontal direction when the substrate is supported in the process chamber, and
wherein, in (b), the heater is operated when at least thermal attenuation rates of thermal attenuators respectively provided on holders in the combinations arranged circumferentially are substantially equal.

15. A method of manufacturing a semiconductor device, comprising the method of claim 1.

16. A substrate processing apparatus configured to be capable of performing the method of claim 1.

17. A lamp module configured to be capable of performing the method of claim 1.

18. A method of processing a substrate, comprising:
(a) loading the substrate into a process chamber;
(b) operating a heater comprising a lamp capable of radiating a light to heat the substrate and a storage capable of storing a wiring connected to the lamp; attenuating a heat generated by the light radiated from the lamp by a thermal attenuator provided at a location of a first structure facing the lamp, wherein the first structure is provided at a holder and configured to cover an outer periphery of the storage; and forming a heat conduction path of a heat of the storage to a housing via the first structure, a second structure provided at the holder and a support of the housing, wherein the second structure protrudes outward from another location of the first structure opposite to the lamp, and wherein the housing is provided above the process chamber and comprises an insertion structure into which the first structure is inserted in a non-contact state and the support configured to support the second structure; and
(c) heating the substrate by the heater.

19. A non-transitory computer-readable recording medium storing a program that causes a substrate processing apparatus, by a computer, to perform:
(a) loading a substrate into a process chamber;
(b) operating a heater comprising a lamp capable of radiating a light to heat the substrate and a storage capable of storing a wiring connected to the lamp; attenuating a heat generated by the light radiated from the lamp by a thermal attenuator provided at a location of a first structure facing the lamp, wherein the first structure is provided at a holder and configured to cover an outer periphery of the storage; and forming a heat conduction path of a heat of the storage to a housing via the first structure, a second structure provided at the holder and a support of the housing, wherein the second structure protrudes outward from another location of the first structure opposite to the lamp, and wherein the housing is provided above the process chamber and comprises: an insertion structure into which the first structure is inserted in a non-contact state; and the support configured to support the second structure; and
(c) heating the substrate by the heater.
